(19) United States
(12) Patent Application Publication
(10) Pub. No.: US 2005/0094696 A1
(43) Pub. Date: May 5, 2005

(54) Compact front facet tap for laser device

(76) Inventor: Sylvain Colin, Redwood, CA (US)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/701,303

(22) Filed: Nov. 4, 2003

(51) Int. Cl. H01S 5/00

(52) U.S. Cl. 372/50; 372/703

(57) ABSTRACT

A laser device that includes structure to tap laser output energy, e.g., to measure output power levels, is provided. The laser device includes a laser source and an optical objective that is able to couple laser energy from the laser device to an output device, such as a fiber. The laser device also includes an optical isolator to prevent back reflections and back scattered light from impinging on the laser device. Normally, the only function of the optical isolator is to ensure that no light reflects back toward the laser source. In an example, the isolator provides a reflection of the laser beam to a monitor photodiode. A front face of the optical isolator is tilted relative to the laser source and the lens to reflect a portion of the laser output energy back into the lens, which may focus the reflected portion onto a photodiode. The photodiode may be used to measure the intensity of the laser output energy. In some embodiments, the objective is a single lens; in others, multiple lenses may be used. The objective and optical isolator may be positioned to couple the reflected portion to a spot laterally displaced from the laser source. Such lateral displacement allows the laser source and a photodiode to be fabricated together and/or mounted to the same submount, thereby reducing the overall size of the laser device in comparison to known devices.

### TECHNICAL FIELD OF THE DISCLOSURE

The present disclosure relates to a laser device and, more particularly, to a laser transmitter using a photodiode for laser performance monitoring.

### BACKGROUND OF THE RELATED ART

Laser devices like network transmitters and transponders often monitor output power levels as part of a control scheme to optimize device performance. The importance of regulating output power levels has been known for years. Yet, as the number of optical components within a communications network (e.g., transponders, optical fibers, switches, amplifiers, repeaters, etc.) increases, power regulation has become more of an issue for component designers. Across the network, power regulation improves data integrity and prolongs device lifetime.

The typical power regulation technique uses monitoring photodiodes to measure a portion of the laser device's output energy. A controller receives a current signal from the photodiode and determines if the laser device is operating within an acceptable output power range. If the device is not, then the controller may correspondingly adjust the laser's power supply, an external modulator, or an associated attenuator to achieve the desired output power level.

Generally, there are two techniques for measuring the output power of a laser. FIG. 1 illustrates a first technique, where a laser system 100 has a source laser 102, such as, an edge emitting laser configured in a Fabry Perot or a distributive feedback (DFB) configuration. The laser 102 has a primary output energy 104. The laser 102 provides a backward, or secondary, output energy 106 from a partially-transmitting back facet 108. The backward output energy 106 is proportional, in intensity, to the intensity in the output energy 104 and is coupled to a photodiode 110 for measurement.

One problem with this design is that it is unusable for certain lasers. For external cavity lasers, the front and back power may not be proportional. In some lasers, the laser cavity is formed by a semiconductor chip with one face acting as the first mirror and an external mirror acting as the second. For Vertical Surface Emitting Lasers (VCSEL), there may be no emission from the back face at all.

Another technique for monitoring output power is shown in FIG. 2 where a system 150 includes a laser source 152, which in this example may be a single-face side emitting laser or vertical cavity surface emitting laser (VCSEL). In the illustrated example, an output 154 from the laser 152 is coupled into a coupler 156 that includes a beam splitter 158. An output energy 160 from the beam splitter is coupled to a photodiode 162 and is proportional to a primary output energy 164. The dimensions of the beam splitter assembly substantially add to overall device size and cost. And size and cost are primary design considerations for modern transponders and other network devices.

### BRIEF DESCRIPTION OF THE DRAWINGS

FIG. 1 is a block diagram of a prior art two-facet laser system having a photodiode positioned at a back facet.

FIG. 2 is a block diagram of a prior art laser system having a collimator and beam splitter that couple energy into a photodiode.

FIG. 3 is an illustration of a laser device with an optical isolator positioned to couple energy into a photodiode.

FIG. 4 is an illustration of a partially-assembled laser device including the structures shown in FIG. 3.

FIG. 5 is an illustration of an example optical isolator that may be used in the device of FIG. 3.

FIG. 6 is an example ray-tracing illustration of the lens and isolator of FIG. 3.

FIG. 7 illustrates an alternative laser device including an optical isolator and two-lens system.

FIG. 8 illustrates a transponder including a laser device such as those illustrated in FIGS. 3 and 7.

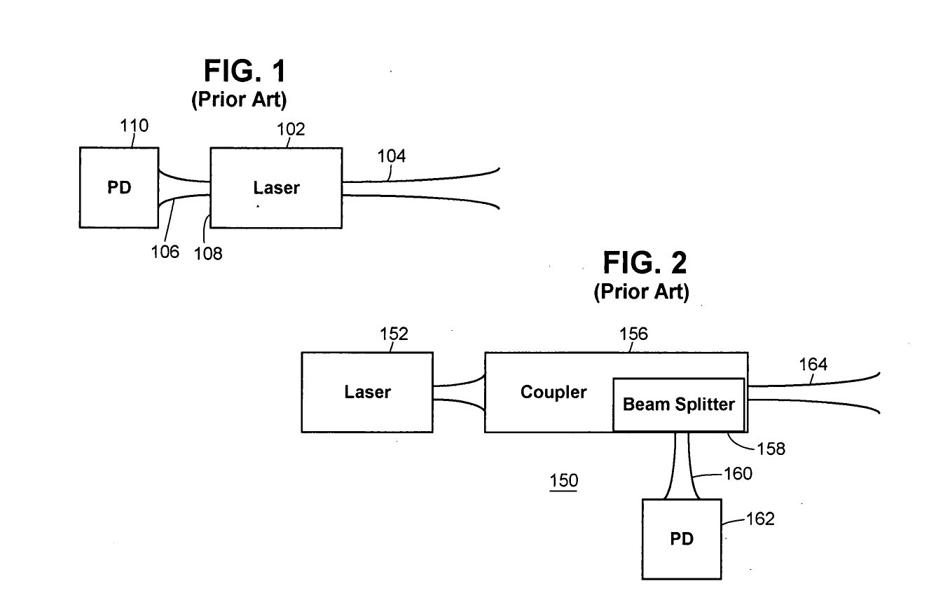

### DETAILED DESCRIPTION OF AN EXAMPLE

In some communication devices, optical isolators are used to prevent backward traveling or backward scattered waves from impinging on the device's laser source. Substantial amounts of energy can exist in a backward wave as a result of boundary reflections or back-scattering phenomena, such as stimulated Brillouin scattering. Proposed herein are techniques and apparatuses for using existing optical isolators to assist in the monitoring of output energy of a laser device. Although the examples may be described with reference to laser devices such as those that may be used in transponders and transmitters, persons of ordinary skill in the art will recognize that the attendant descriptions may be implemented in sensors, amplifiers, switches, routers, and other optical devices having optical isolators and which may benefit from output signal monitoring.

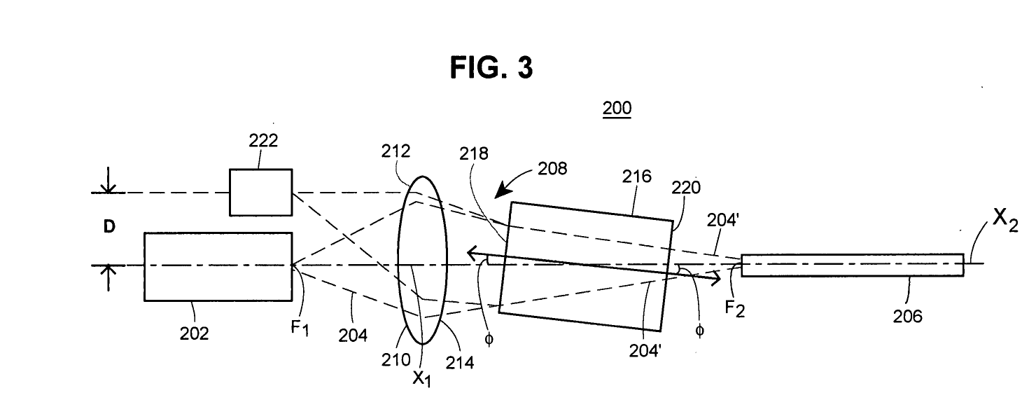

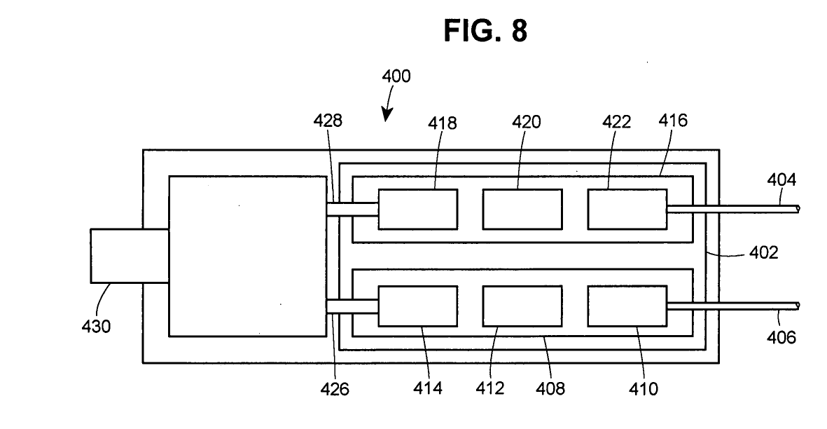

FIG. 3 illustrates an example optical device 200 that includes a laser 202 that provides an output signal 204 to be coupled to an output device in the form of an optical fiber 206. The fiber 206 may be a single-mode fiber or a multi-mode fiber for propagating multiple information carrying laser signals. For simplification purposes, modulation stages, filter/tuner stages, and amplification stages are not illustrated. These stages may be used as the output device or between the output device and the laser source. For example, FIG. 8 shows a laser output signal coupled to a modulator as the output device.

The device 200 includes a coupling stage 208 that includes a lens 210 with a principle axis, x1, aligned with an axis, x2, extending between the laser 202 and the output device, fiber 206. Alignment is not necessary; the axes x1 and x2 may be misaligned, instead. In the illustrated example, the lens 210 couples part of the energy 204 into the fiber 206 through the isolator 216. The laser source 202, the fiber 206 and the lens 210 are positioned to reach the adequate coupling for the application. This coupling typically ranges from 10% in short range transmitter to 90% for long-range transmitter.

The isolator 216 protects the laser source 202 from backward waves. Unlike the lens 210, the optical isolator 216 is not aligned about the axis, x2. Instead, the isolator 216 has a front face 218 and a parallel, back face 220 that are both angled an angle, φ, with respect to the axis, x2. The angle, φ, is adjustable across a range of angles, and may be between 0-15°, in one example.

A majority of the energy 204 is provided as the energy 204′. A portion of the energy 204, is reflected off of the front face 218 of the isolator 216. Laser energy reflected from the face 218 is reflected back into the lens 210 and focused onto a photodiode 222 that is laterally displaced from the laser 202 by a distance, D. The lateral distance, D, is dependent upon the angle, φ. The walk-off distance D increases with higher angles, φ. In the illustrated example, the photodiode 222 being laterally displaced from the laser 202 allows for greater compactness. Nevertheless, the photodiode may be positioned elsewhere. The amount of energy reflected by the isolator 216 is adjustable by applying different reflective coatings to the face 218.

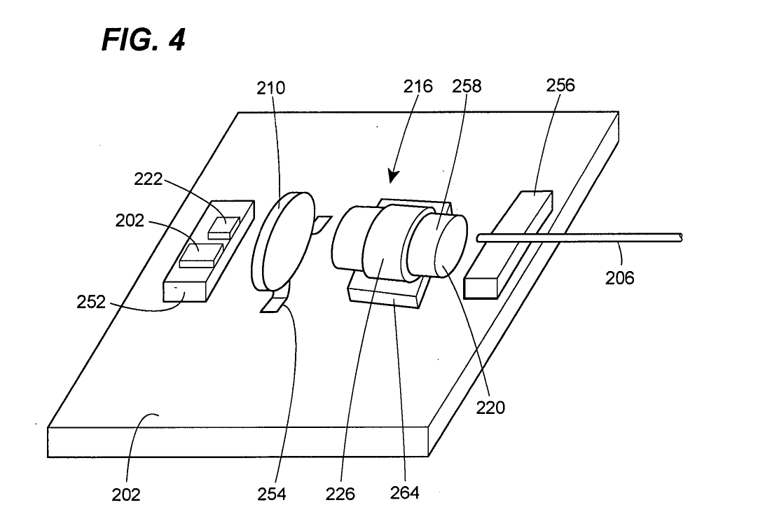

FIG. 4 illustrates the system 200 of FIG. 3 in a partially assembled device form that may be part of a transmitter or transponder. The device 200′ has a support substrate 250 with a laser/photodiode submount 252 mounted thereon. In the illustrated example, the laser 202 and the photodiode 222 have been formed on the submount 252 and then mounted to the substrate 250 by techniques such as glue mounting, fusion bonding, clamping, or workbench mounting. The submount 252 includes control circuitry and electrical leads (not shown) and may additionally provide thermal isolation of the laser 202 and the photodiode 222.

The lens 210 is mounted to the substrate 250 via a flexure 254, in the illustrated example. A fiber support 256 is also mounted to the substrate 250 using techniques described herein. The support 256 may include a v-groove recess sized to accept the fiber 206 glued or clamped therein. Other fiber or pigtail mountings will be known to persons of ordinary skill in the art.

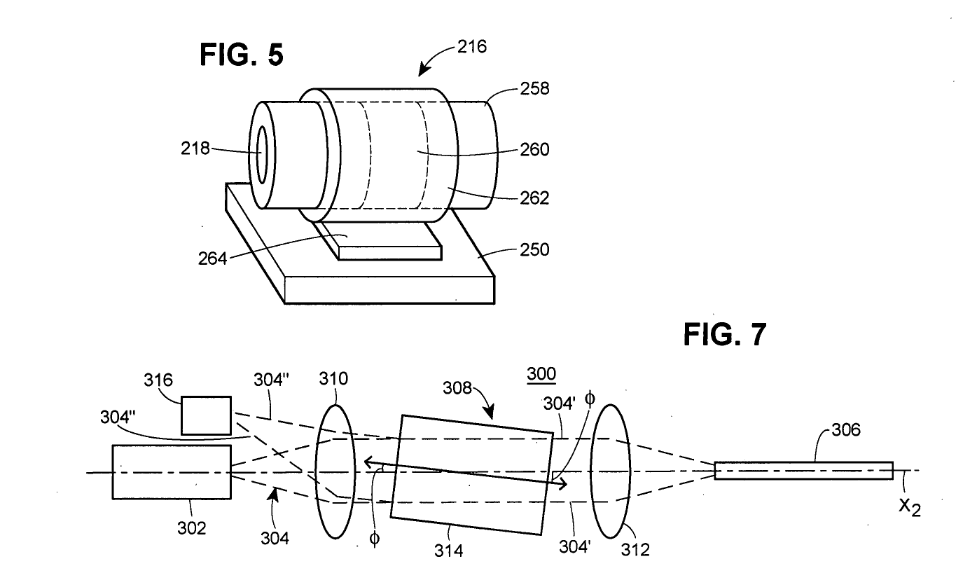

The optical isolator 216 is shown in more detail in FIG. 5. The isolator 216 includes the front face 218 defining an aperture opening into a housing 258 having an annular-shaped magnet, or other ferrule active material, 260 (dashed lines). The front face 218 and the back face 220 (not shown) may have polarizing materials having orthogonally oriented polarization states. The back face 220 may be coated with an anti-reflection coating to reduce insertion loss, if desired. The front face 218 may be coated with reflective material to adjust the amount of reflection in the photodiode. A holder 262 is mounted around the housing 258, and a support 264 affixed to the holder 262 is attached to the substrate 250 using the techniques described herein.

The offset angle, φ, for the isolator 216 may be predetermined prior to assembly. Alteratively, the offset may be set by operating the laser 202 with the isolator 216 temporarily in place and rotating the position of the isolator 216 relative to the axis, x2, until the desired amount of reflected energy is detected by the photodiode 222. From this calibrated position, the isolator 216 may be bonded in place on the substrate 250. Because only slight tilting angles, φ, are used, the isolator offset will have a limited affect on the position of the coupled light 204′ into the fiber 206.

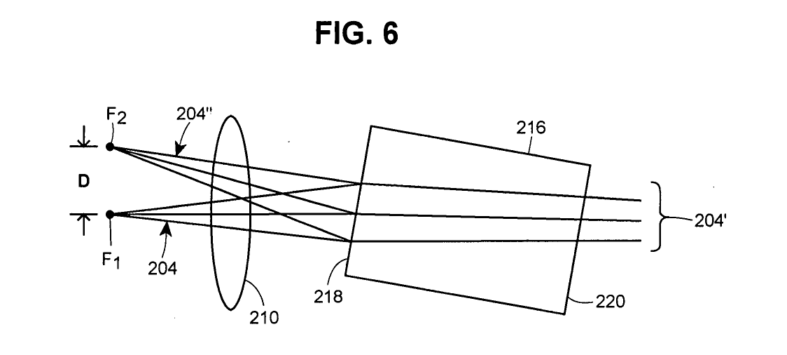

FIG. 6 illustrates a top view of the isolator 216 and the lens 210. Laser energy from a first point source, e.g., a laser, is coupled from the focal point F1 into the lens 210 and through the isolator 216 as the energy 204′. Another portion of other output energy 204 (labeled 204″) reflects off the face 218 and is coupled through the lens, which focuses that energy to the focal point F2. The focal points F1 and F2 are separated by the walk-off distance, D.

The illustrated examples of FIGS. 3-6 may be altered, such as the system 300 depicted in FIG. 7. In the illustrated example, a laser 302 provides an output energy 304 that is coupled into a fiber 306, by a coupler 308, similar to the coupler 208. The coupler 308 differs in that it includes a first lens 310 and second lens 312, configured as collimators. An isolator 314 is positioned between the lenses 310, 312, such that a collimated energy 304′ propagates through the isolator 314. The isolator 314 has been tilted an angle, φ, with respect to an axis, x2, to cause a portion of the output 304′ to be reflected (as energy 304″) and pass through the lens 310, which focuses the same on a photodiode 316.

FIG. 8 shows an example high-level block diagram of a transponder 400. The transponder 400 includes a transceiver 402 for transmitting and receiving data streams along fibers 404 and 406, respectively. A receiver stage 408 includes a photodiode 410, a trans-impedance amplifier 412, and a separate boosting amplifier 414. A transmitter stage 416 includes a laser device 418 that may be similar to any of the laser devices described hereinabove such as those illustrated in FIGS. 3 and 7. The transmitter stage 416, thus, in an example includes at least one photodiode for monitoring a wave reflected off of an optical isolator within the laser device 418. In the illustrated example, the output of the laser device 418 is coupled to an output device in the form of an external modulator 420, which is coupled to an amplifier 422. The external modulator 420 and the amplifier 422 are shown by way of example and may be integrated into the laser device 418, external to the transponder 400 or removed completely with the laser device output coupled directly to the fiber 404, similar to FIGS. 3 and 7. While a single transceiver 402 is shown, it will be understood by persons of ordinary skill in the art that the transponder 400 may have multiple transceivers or that each depicted block may represent a bank of blocks. For example, the blocks 410 and 418 may be a plurality of photodiodes or laser devices, respectively.

The transceiver 402 is connected to a controller 424, which may represent a microprocessor, for example. A bus 426 connects the receiver stage 408 to the controller 424, and a bus 428 connects the transmitter stage to the controller 424. For the receiver stage 408, the controller 424 may include a deserializer and decoder coupled with the bus 416. For the transmitter stage 416, the controller 424 may include an encoder and a serializer coupled with the bus 428.

In operation, a multi-channel or single channel data stream is received on the fiber 406. The multi-channel data-stream is coupled into the photodiode 410 for optical-to-electrical signal conversion. Data from the photodiode 410 is coupled to the trans-impedance amplifier 412 and sent on to the amplifier 414 prior to being sent to the deserializer within the controller 424 via the bus 426. The deserializer provides a 10 bit signal to the decoder, which decodes the input signal and creates a 10 bit word that may be passed to a Gigabit Media Independent Interface (GMII) bus 430. For data transmission, input data from the GMII is first encoded by the encoder and then serialized by the serializer to create a transmittable serial bit stream. The output from the serializer is provided on the bus 428 and controls the output of the laser device 418. The laser device 418 includes an optical isolator positioned to tap a portion of the output energy back into a photodiode positioned adjacent the laser source of the laser device 418. The monitored signal from this photodiode is used by the controller 424 or control circuitry within the transmitter stage 416 to adjust the output intensity of the laser device 418 or to adjust the amount of amplification from the amplifier 422. This feedback control may be a separate control having predetermined output power intensity levels. The control may measure output energy from the laser device 418 directly or, alternatively, it may measure output energy from the amplifier 422, for example, by positioning the optical isolator downstream of the amplifier 422 and positioning a photodiode to collect the partially reflected energy. In the illustrated example, the output signal from the laser device 418 is modulated by the modulator 420 and then amplified by the amplifier 422 prior to transmission on the fiber 404.

While the illustration of FIG. 8 is an example, it will be understood by persons of ordinary skill in the art that additional control blocks and routines may be used or that some of the control blocks of FIG. 8 may be eliminated or replaced. Additionally, the controller 424 may include an internal clock, a clock and data recovery device (CDR), phase control via phase locked loops (PLL), and/or error correction control circuitry. Furthermore, while not necessary, the transponder 400 may be compliant with any known network communications standards of which SONET formats OC-48 (2.5 Gbps), OC-192 (10 Gbps), and OC-768 (40 Gbps) are examples.

The embodiments illustrated and described herein are provided by way of example only numerous modifications and changes may be made to the illustrated embodiments. For example, the laser device may couple the collimated beam to other downstream devices, such as active or passive optical devices (e.g., modulators, amplifiers, or filters) in place of a focusing lens. Furthermore, the distances between the laser and the fiber may be chosen to increase compactness. Further still, the focal lengths and tilt angles, φ, may be chosen to focus the reflected beam onto various spot sizes. As a result, a photodiode ranging from above 500 μm in diameter to below 100 μm in diameter may be used. These are provided by way of example only.

Also, other optical objective components may be used in place of or in addition to the lenses described. Multiple lens objectives, prisms, and mirrors are examples, as well as apertures that reduce beam spot size.

By way of further example, the laser sources described above may be any of a variety of laser sources including semiconducting edge emitting lasers, VCSELS, external cavity lasers, and laser amplifiers. The lasers may represent active or passive laser sources, as well. Persons of ordinary skill in the art will appreciate other alternatives from the foregoing description and in light of the following claims.

Although certain apparatus constructed in accordance with the teachings of the invention have been described herein, the scope of coverage of this patent is not limited thereto. On the contrary, this patent covers all embodiments of the teachings of the invention fairly falling within the scope of the appended claims either literally or under the doctrine of equivalence.

1. A laser device for use in coupling a laser energy into an output device, comprising:
a laser source disposed on a substrate, the laser source producing the laser energy;
a photodiode disposed on substrate; and
an optical isolator disposed between the laser source and the output device, the optical isolator having a front face aligned to partially reflect the laser energy from the laser source onto the photodiode.

2. The laser device of claim 1, further comprising a submount mounted to the substrate, wherein the photodiode and the laser source are mounted to the submount.

3. The laser device of claim 1, further comprising a first lens disposed between the laser source and the optical isolator, the first lens positioned to couple the laser energy to the output device and positioned to couple the partially reflected laser energy to the photodiode.

4. The laser device of claim 3, wherein the laser source and the first lens are aligned on a first optical axis and wherein the optical isolator defines a second optical axis that forms an acute angle with the first optical axis.

5. The laser device of claim 4, wherein the acute angle is between 0 and 15 degrees.

6. The laser device of claim 4, wherein the optical isolator has a back face parallel to the front face.

7. The laser device of claim 1, further comprising:
a first lens disposed to couple the laser energy into the optical isolator as a collimated beam and disposed to couple the partially reflected laser energy to the photodiode; and
a second lens disposed to receive the collimated beam and couple the collimated beam to the output device.

8. The laser device of claim 1, wherein the photodiode is laterally displaced from the laser source.

9. A method of tapping a portion of a laser energy from a laser device having a laser source and an output device, the method comprising:
disposing a lens between the laser source and the output device to couple the laser energy from the laser source into the output device;
disposing an optical isolator between the lens and the output device;
disposing the optical isolator in a tilted configuration to reflect the portion of the laser energy through the lens and onto a desired location laterally displaced from the laser source.

10. The method of claim 9, further comprising disposing a photodiode at the desired location to detect the portion of the laser energy.

11. The method of claim 9, wherein the optical isolator is disposed such that a front face of the optical isolator forms an acute angle with an axis defined by the laser source.

12. The method of claim 9, wherein the optical isolator has a back face parallel to the front face.

13. The method of claim 9, further comprising disposing a second lens between the optical isolator and the output device, wherein the first lens and the second lens form a collimating lens pair.

14. A transponder comprising:
a receiver stage;
a controller; and
a transmitter stage, the controller being coupled to the receiver stage and the transmitter stage for receiving and transmitting data, the transmitter stage comprising:
a laser source for producing a laser energy;
an optical objective positioned between the laser source and an output device to couple the laser energy from the laser source to the output device; and
an optical isolator positioned to reflect a portion of the laser energy through the optical objective and onto a location laterally displaced from the laser source.

15. The transponder of claim 14, wherein the transmitter stage further comprises a photodiode positioned adjacent the location laterally displaced from the laser source.

16. The transponder of claim 15, wherein the laser source and the photodiode are formed on a submount.

17. The transponder of claim 14, wherein the optical isolator is tilted relative to an optical axis defined by the laser source.

18. The transponder of claim 14, wherein the optical objective comprises a first lens and a second lens, wherein the optical isolator is positioned between the first lens and the second lens.

19. The transponder of claim 14, wherein the optical objective comprises a lens positioned to couple the laser energy to the output device and positioned to couple the partially reflected laser energy to the location laterally displaced from the laser source.

20. The transponder of claim 14, wherein the receiver stage comprises:
a photodiode;
a trans-impedance amplifier; and
a boosting amplifier.

21. The transponder of claim 14, wherein the transmitter stage further comprises:
a modulator; and
an optical amplifier coupled to receive the laser energy.
